(19) United States
(12) Patent Application Publication
(10) Pub. No.: US 2019/0051720 A1
(43) Pub. Date: Feb. 14, 2019

(54) SEMICONDUCTOR INTEGRATED CIRCUIT DEVICE

(71) Applicant: KEIO UNIVERSITY, Tokyo (JP)

(72) Inventor: Tadahiro Kuroda, Yokohama-shi (JP)

(73) Assignee: KEIO UNIVERSITY, Tokyo (JP)

(21) Appl. No.: 16/074,535

(22) PCT Filed: Jan. 26, 2017
(86) PCT No.: PCT/JP2017/002652

§ 371 Date: Aug. 1, 2018

(30) Foreign Application Priority Data
Feb. 3, 2016 (JP) 2016-018817

(51) Int. Cl. H01L 49/02; H01L 23/528; H01L 23/522

(52) U.S. Cl. CPC H01L 28/10; H01L 23/5226; H01L 23/5227; H01L 23/5286

(57) ABSTRACT

The invention relates to a semiconductor integrated circuit device where it is made possible to achieve both an improvement in the degree of inductive coupling between coils and suppression of the power supply voltage drop in the power supply wires. A power supply network is provided with: a first power supply wire group that passes through the inside of every coil of a first coil array formed in the same level in a multilayered wire structure provided on a substrate, in the X direction as viewed in the direction in which the multilayered wire structure is layered, and a second power supply wire group that passes through the inside of every coil in the Y direction, wherein at least part of the first power supply wire group and at least part of the second power supply wire group form a closed circuit that surrounds the periphery of each coil.

### TECHNICAL FIELD

The present invention relates to a semiconductor integrated circuit device, and in particular, relates to the configuration of a power supply network that does not prevent inductive coupling in a semiconductor integrated circuit device having transmission and reception coils for data communication using inductive coupling.

### BACKGROUND ART

A magnetic field passes through a semiconductor chip. When a coil for transmission and a coil for reception that are fabricated by winding a wire on a semiconductor chip are arranged in close proximity and a current that flows through the transmission coil is changed in accordance with a signal, the magnetic field around the coils change together. At this time, a voltage signal is induced in the reception coil, and the signal is decoded via a reception circuit. Such data communication using inductive coupling is used for a digital signal connection between chips that are layered on top of each other.

Data communication using inductive coupling is characterized in that the electronic connection by means of integrated circuits provides a high yield in the manufacture, which lowers the cost, as compared to conventional mechanical connections such as the connection between chips that are layered on top of each other using through silicon vias (TSVs). In addition, the electromagnetic field that becomes a signal can pass through the semiconductor substrate where transistors are provided, which lowers restrictions in terms of the connection location between coils, and therefore, data communication using inductive coupling has such advantages that high-speed communication can be achieved by increasing the number of communication channels or the power can be made low because a static electricity protection circuit is not required.

When there is a metal plate in the vicinity of a coil, however, an inductive current in eddy form (eddy current) is generated within the metal in such a direction as to cancel the change in the magnetic field due to the electromagnetic induction effects, and as a result, the inductive coupling between coils is weakened. The lower the resistance of the metal plate is, the greater the change in the eddy current becomes, which makes the force for cancelling the change in the magnetic field in the periphery stronger.

The transmission and reception coils provided in the semiconductor chips are coreless, and therefore, the change in the magnetic field is stronger in the periphery of the sides of the coils. Accordingly, a closed circuit through which an eddy current flows along the sides of a coil is provided near the sides of the coil when there is a metal plate in the vicinity of the coil. It is expected that the lower the electrical resistance of this path is, the weaker the inductive coupling is.

Meanwhile, in many cases, the power supply wire that is installed on a semiconductor chip is in mesh form. The electrical resistance may be lowered in order to prevent the power supply voltage from dropping in the power supply wire, and in order to do so, a power supply network that is fine and has a low resistance is installed. Thus, the power supply network and the inductive coupling of the coils are in a trade-off relationship where if the power supply voltage drop is improved, then the inductive coupling between the coils deteriorates, whereas if the inductive coupling between the coils is improved, then the power supply voltage drop deteriorates, and therefore, it becomes important to satisfy the requirements from both sides.

Accordingly, the present inventors carried out detailed examinations using an electromagnetic field simulation, and in addition designed, test manufactured a test chip, and measured the data of a test chip, and thus diligently searched for the relationship between the electrical resistance of the power supply network and the inductive coupling between the coils (see Non-Patent Literature 1 and 2).

As illustrated in Non-Patent Literature 1 and 2, it was confirmed that the inductive coupling significantly dropped when an eddy current flew through the closed circuit along the sides of a coil, whereas the inductive coupling barely dropped when no eddy current flew through the closed circuit. As illustrated in FIG. 28, according to the results of the experiment using a test chip, it was confirmed that the further the closed circuit through which an eddy current flew was shifted away from the sides of a coil, the stronger the recovery of the inductive coupling was. Here, the symbol Z in FIG. 28 denotes the distance between the transmission coil and the reception coil.

FIG. 28 is a graph illustrating the dependency of the degree of inductive coupling on the ratio of the distance X between the closed circuit through which an eddy current flows and the sides of a coil to the side length D of the coil. As illustrated in FIG. 28, the degree of inductive coupling lowers to approximately 20% (approximately ⅕) when an eddy current flows along the sides of a coil (X/D=0). Meanwhile, it can be seen that the degree of inductive coupling recovers to approximately 50% (approximately ½) when an eddy current flows through a place that is the distance 0.5 times greater than the length D of one side of the coil away from the sides of the coil (X/D=0.5).

### CITATION LIST

### Patent Literature

Patent Literature 1: Japanese Unexamined Patent Publication 2015-103584
Patent Literature 2: Japanese Patent No. 5475962

### Non-Patent Literature

Non-Patent Literature 1: L. Hsu, J. Kadomoto, S. Hasegawa, A. Kosuge, Y. Take, and T. Kuroda, “A Study of Physical Design Guidelines in ThruChip Inductive Coupling Channel,” IEICE Trans. on Fundamentals, vol. E98-A, no. 12, pp. 2584-2591, December 2015
Non-Patent Literature 2: L. Hsu, Y. Take, A. Kosuge, S. Hasegawa, J. Kadomoto, and T. Kuroda, “Design and Analysis for ThruChip Design for Manufacturing (DFM),” 20^{th} Asia and South Pacific Design Automation Conference (ASP-DAC '15), Proceedings, pp. 46-47, Jan. 19-22. 2015

### SUMMARY OF INVENTION

### Problems to be Solved by the Invention

In Non-Patent Literature 1 and 2, how the deterioration of the power supply voltage drop is suppressed is not concretely examined when the inductive coupling between the coils is improved.

Therefore, an object of the invention is to provide a semiconductor integrated circuit device where an improvement in the degree of inductive coupling between coils and suppression of the power supply voltage drop in the power supply wire are achieved at the same time.

### Means for Solving the Problems

One aspect of the disclosed invention provides a semiconductor integrated circuit device with: a first coil array made of a plurality of coils that are formed in the same level in a multilayered wire structure provided on a substrate and are arranged at predetermined intervals; and a power supply network having a first power supply wire group made of power supply wire pairs of a power supply wire and a ground wire that pass through the inside of every coil in the X direction as viewed in the direction in which the multilayered wire structure is layered, and a second power supply wire group made of power supply wire pairs of a power supply wire and a ground wire that pass through the inside of every coil in the Y direction that is orthogonal to the X direction as viewed in the direction in which the multilayered wire structure is layered, wherein at least part of the first power supply wire group and at least part of the second power supply wire group form a closed circuit that surround the periphery of each coil.

### Advantageous Effects of the Invention

The disclosed semiconductor integrated circuit device makes it possible to achieve both an improvement in the degree of inductive coupling between coils and suppression of the power supply voltage drop in the power supply wires through a revision of the power supply network.

### BRIEF DESCRIPTION OF DRAWINGS

FIG. 1 is a plan diagram symbolically illustrating a transmission and reception coil arrangement unit in the semiconductor integrated circuit device according to the embodiment of the present invention.

FIGS. 2A and 2B are diagrams symbolically illustrating a coil.

FIGS. 3A and 3B are diagrams symbolically illustrating power supply wires.

FIGS. 4A and 4B are diagrams symbolically illustrating a case where a coil and power supply wires are combined.

FIGS. 5A and 5B are diagrams symbolically illustrating a coil array and power supply wires.

FIG. 6 is a diagram illustrating the intensity distribution of magnetic fields generated by currents that flow through the coils.

FIG. 7 is a diagram illustrating a closed circuit that is formed in the periphery of a coil and through which an eddy current flows.

FIG. 8 is a graph illustrating the dependency of the degree of inductive coupling on the distance between the power supply wire network and the sides of the coils.

FIGS. 9A and 9B are diagrams illustrating the semiconductor integrated circuit device according to Example 1 of the present invention.

FIG. 10 is a diagram illustrating a closed circuit through which an eddy current flows.

FIGS. 11A and 11B are diagrams illustrating the semiconductor integrated circuit device according to Example 2 of the present invention.

FIGS. 12A and 12B are diagrams illustrating the semiconductor integrated circuit device according to Example 3 of the present invention.

FIG. 13 is a diagram symbolically illustrating an area where a transmission and reception coil array is arranged in the semiconductor integrated circuit device according to Example 4 of the present invention.

FIG. 14 is a diagram illustrating closed circuits through which an eddy current flows.

FIG. 15 is a diagram symbolically illustrating an area where a transmission and reception coil array is arranged in the semiconductor integrated circuit device according to Example 5 of the present invention.

FIG. 16 is a diagram illustrating a closed circuit through which an eddy current flows

FIG. 17 is a diagram symbolically illustrating an area where a transmission and reception coil array is arranged in the semiconductor integrated circuit device according to Example 6 of the present invention.

FIG. 18 is a diagram illustrating closed circuits through which an eddy current flows.

FIG. 19 is a diagram symbolically illustrating an area where a transmission and reception coil array is arranged in the semiconductor integrated circuit device according to Example 7 of the present invention.

FIG. 20 is a diagram illustrating a closed circuit through which an eddy current flows

FIGS. 21A and 21B are diagrams illustrating the semiconductor integrated circuit device according to Example 8 of the present invention.

FIG. 22 is a diagram illustrating a closed circuit through which an eddy current flows

FIGS. 23A and 23B are diagrams illustrating the semiconductor integrated circuit device according to Example 9 of the present invention;

FIG. 24 is a diagram illustrating closed circuits through which an eddy current flows.

FIG. 25 is a diagram illustrating closed circuits through which an eddy current flows.

FIG. 26 is a diagram symbolically illustrating an area where transmission and reception coil arrays are arranged in the semiconductor integrated circuit device according to Example 10 of the present invention.

FIG. 27 is a diagram symbolically illustrating a transmission and reception coil array arrangement area in the semiconductor integrated circuit device according to Example 11 of the present invention; and

FIG. 28 is a graph illustrating the dependency of the degree of inductive coupling on the ratio of the distance X between the closed circuit through which an eddy current flows and the sides of a coil to the side length D of the coil.

### DESCRIPTION OF EMBODIMENTS

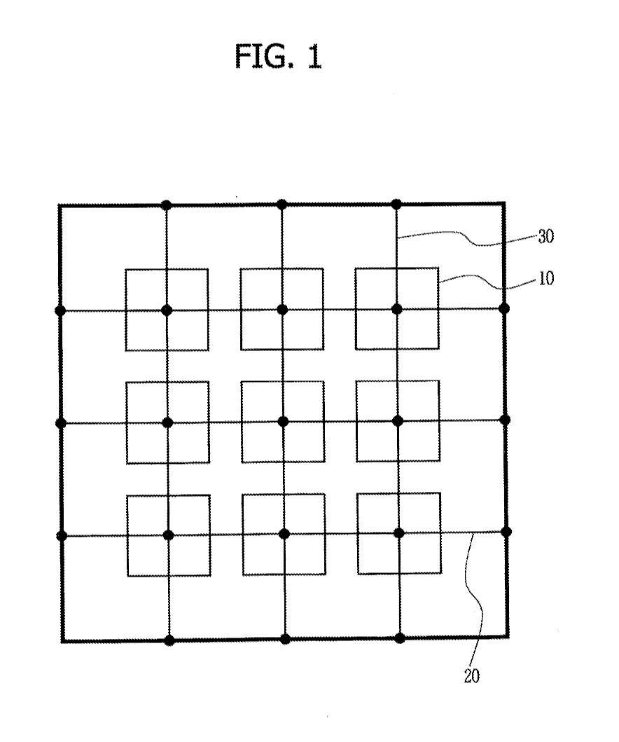

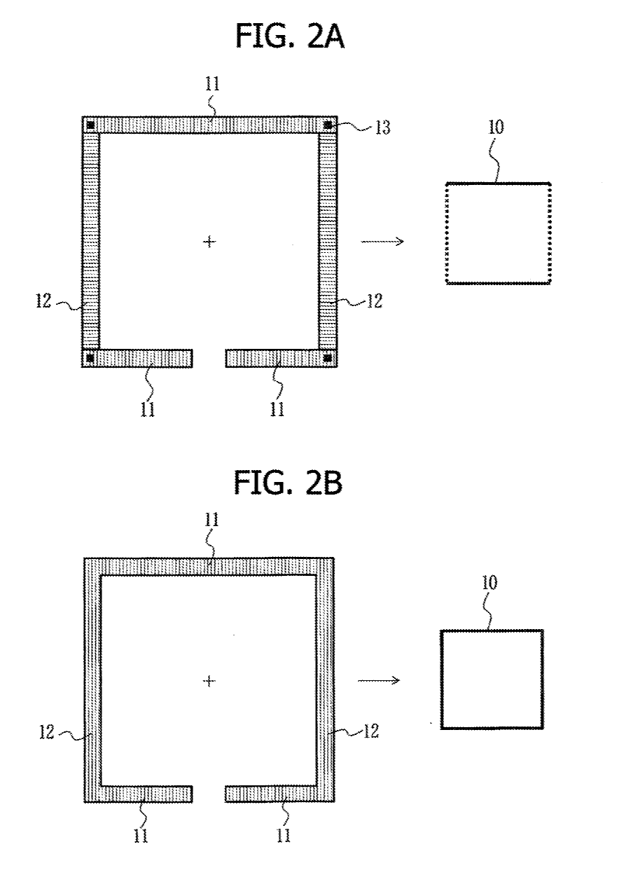

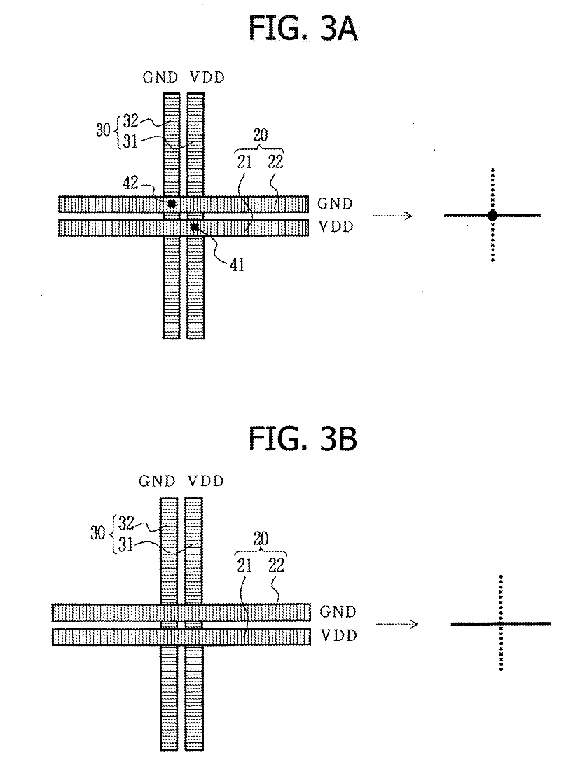

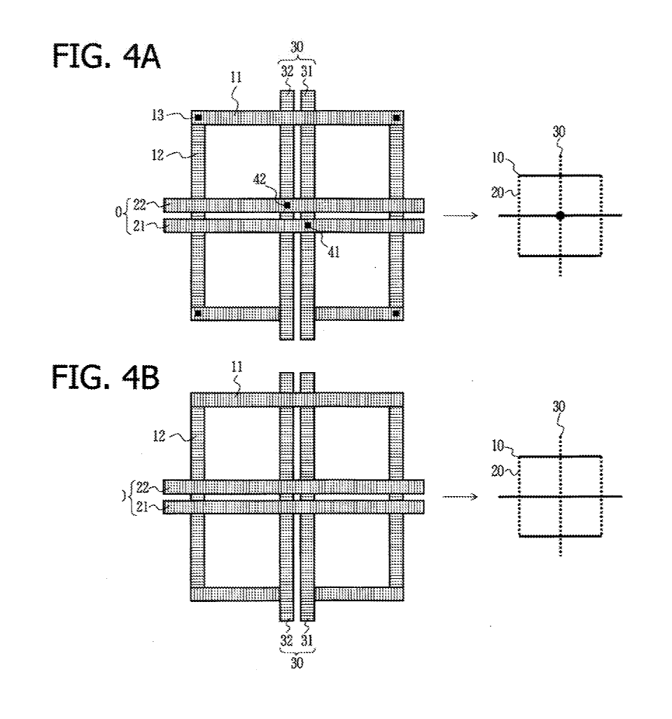

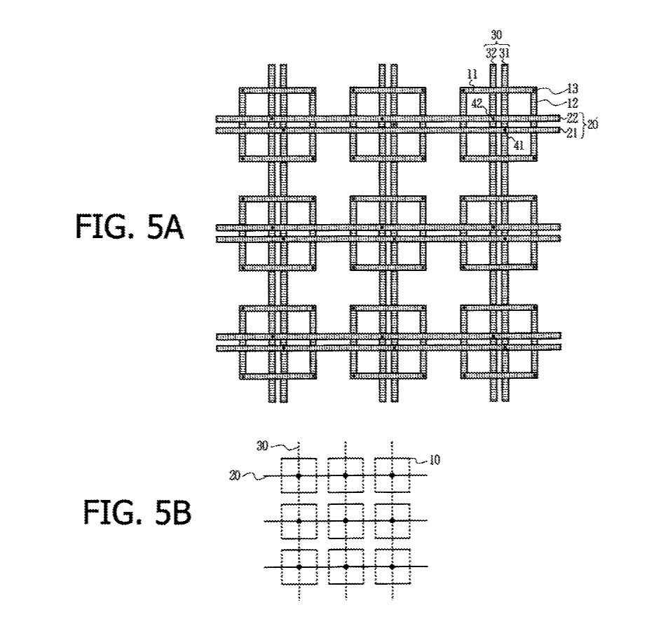

The semiconductor integrated circuit device according to an embodiment of the present invention is described in reference to FIGS. 1 through 8. FIGS. 1 through 4B are diagrams illustrating the structure of the semiconductor integrated circuit device according to an embodiment of the present invention. FIG. 1 is a plan diagram symbolically illustrating a transmission and reception coil arrangement unit in the semiconductor integrated circuit device according to the embodiment of the present invention. FIGS. 2A and 2B are diagrams symbolically illustrating a coil. FIGS. 3A and 3B are diagrams symbolically illustrating power supply wires. FIGS. 4A and 4B are diagrams symbolically illustrating a case where a coil and power supply wires are combined. FIGS. 5A and 5B are diagrams symbolically illustrating a coil array and power supply wires.

As illustrated in FIG. 1, a first coil array made of a plurality of coils 10 arranged at predetermined intervals is formed in the same level in a multilayered wire structure provided on a substrate. A power supply network is provided with a first power supply wire group 20 made of power supply wire pairs of a power supply wire and a ground wire that pass through the inside of each coil 10 in the X direction as viewed in the direction in which the multilayered wire structure is layered, and a second power supply wire group 30 made of a power supply wire and a ground wire that pass through the inside of each coil 10 in the Y direction that is orthogonal to the X direction as viewed in the direction in which the multilayered wire structure is layered. At least part of the first power supply wire group 20 and at least part of the second power supply wire group 30 form a closed circuit that surrounds the periphery of a coil 10. Though FIG. 1 illustrates a coil array of three rows by three columns, the array can be expanded to m rows by n columns.

In this case, the shape of the coils 10 may be rectangular, diamond-shaped, polygonal such as octagonal, or rhombic; however, a square is a typical shape. In the case where the coils 10 are rectangular shaped, as illustrated in FIGS. 2A and 2B, a coil 10 may be formed of first coil elements 11 that are parallel to the first power supply wire group 20 and second coil elements 12 that are parallel to the second power supply wire group 30. In the case where the power supply network is provided with diamond-shaped coils, third coil elements that are oriented in the direction that is diagonal by 45° relative to the first power supply wire group 20, and fourth coil elements that are oriented in the direction that is diagonal by 45° relative to the second power supply wire group 30 may be used.

As illustrated in FIG. 2A, a coil 10 may be provided by forming first coil elements 11 and second coil elements 12 of wires in different layer levels and by alternately connecting the first coil elements 11 and the second coil elements 12 with vias 13. In this case, the number of turns of the coil is arbitrary. Here, FIG. 2A illustrates a plan diagram of a coil on the left and a symbolic diagram of the coil on the right.

As illustrated in FIG. 2B, the first coil elements 11 and second coil elements 12 may be formed of wires in the same layer so that a plane spiral coil is provided. In this case, the first power supply wire group 20 and the second power supply wire group 30 are formed of wires in a layer level that is different from the layer level of the first coil elements 11 and the layer of the second coil elements 12. Here, FIG. 2B illustrates a plan diagram of a coil on the left and a symbolic diagram of the coil on the right. Alternatively, a wire may be wound as a vertical solenoid or in a combination of a plane spiral coil and a vertical solenoid. In the case where a vertical solenoid is formed, for example, metal wires M2 and M3 may be wound, and after that, M4 and M5 may be wound where Mn is a metal wire in the n layer.

As illustrated in FIGS. 3A and 3B, the first power supply wire group 20 and the second power supply wire group 30 are respectively made of power supply wire pairs of a power supply wire 21, 31 and a ground wire 22, 32. In the case of FIG. 3A, a power supply wire 21 and a power supply wire 31 in different layer levels are connected through a via 41 in the place where they respectively intersect, and a ground wire 22 and a ground wire 31 in different layer levels are connected through a via 42 in the place where they respectively intersect. Here, FIG. 3A illustrates a plan diagram of power supply wires on the left and a symbolic diagram of the power supply wires on the right. In addition, FIG. 3B illustrates a case where both the power supply wires 21 and 31 and the ground wires 22 and 32 are not connected in the place where they respectively intersect. Here, FIG. 3B illustrates a plan diagram of power supply wires on the left and a symbolic diagram of the power supply wires on the right.

FIGS. 4A and 4B are diagrams symbolically illustrating a case where a coil and power supply wires are combined. FIG. 4A illustrates a case where both the power supply wires 21 and 31 and the ground wires 22 and 32 are connected in the place where they respectively intersect inside the coil 10. In addition, FIG. 4B illustrates a case where both the power supply wires 21 and 31 and the ground wires 22 and 32 are not connected in the place where they respectively intersect inside the coil 10. FIGS. 4A and 4B illustrate a plan diagram in the case where a coil and power supply wires are combined on the left, and a symbolic diagram of the same on the right.

FIGS. 5A and 5B are diagrams symbolically illustrating a coil array and power supply wires. FIG. 5A is a plan diagram illustrating a coil array and power supply wires, and FIG. 5B is a symbolic diagram illustrating the same. FIG. 1 illustrates what is illustrated in FIG. 5B with power supply wires provided in the periphery of the chip being added. Here, a case is illustrated where both the power supply wires 21 and 31 and the ground wires 22 and 32 are connected in the place where they respectively intersect inside each coil 10; however, the power supply wires 21 and 31 and the ground wires 22 and 32 do not need to be connected in the place where they respectively intersect inside each coil. That is to say, the power supply wires 21 and 31 and the ground wires 22 and 32 may be selectively connected in the place where they respectively intersect inside some of the coils 10. Alternatively, the power supply wires 21 and 31 and the ground wires 22 and 32 may be selectively connected in the place where they respectively intersect inside the coils at predetermined intervals. Furthermore, one end of the power supply wires 21 and 31 may be made an open end, and at the same time, one end of the ground wires 22 and 32 may be made an open end. In this case, the power supply wires 21 and 31 and the ground wires 22 and 32 may be respectively connected in the periphery of the coil columns in such a manner that the power supply wire pairs that connect the connected places form a closed circuit. Typically, power supply wire pairs provided in the periphery of the chip form a closed circuit.

In the case where power supply wires 21 and 31 and ground wires 22 and 32 are selectively connected in the place where they respectively intersect inside some of the coils 10 or inside the coils at predetermined intervals, a plurality of closed circuits are formed for a coil that is focused on. As a result of overlapping of the effects from a number of closed circuits, the inductive coupling of the focused coil lowers. However, the path of an eddy current expands, which makes the electrical resistance greater and the eddy currents effects smaller, and as a result, the inductive coupling is prevented from lowering.

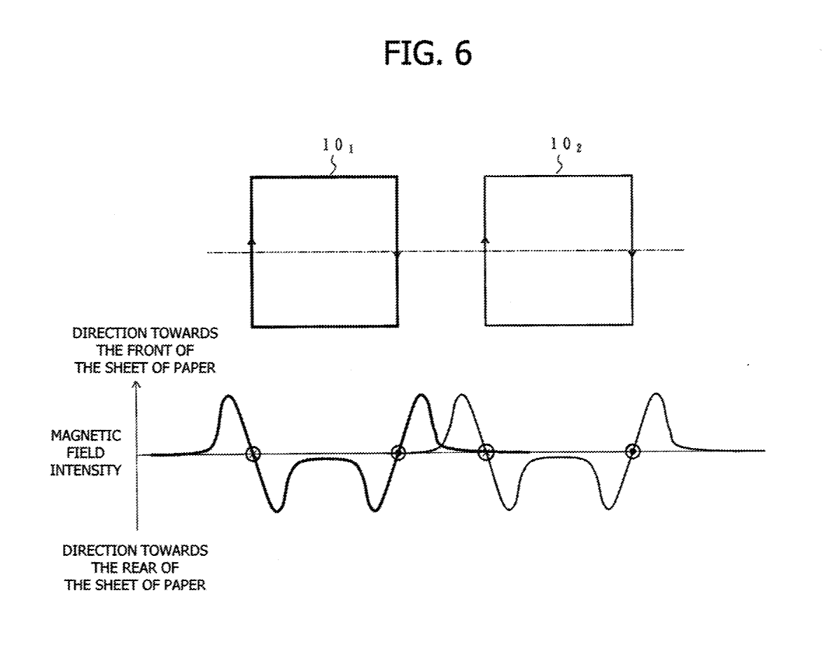

FIG. 6 is a diagram illustrating the intensity distribution of magnetic fields generated by currents that flow through the coils. Since the coil 10₁ does not have a core, the magnetic field is strong in the periphery of the sides of the coil 10₁. Meanwhile, the magnetic fields around the sides that face each other overlap in the same direction inside the sides of the coil 10₁, and therefore, the magnetic field is stronger than the outside of the sides of the coil 10₁. However, another coil 10₂ is arranged outside the coil 10₁ in close proximity. The higher the density of the coil arrangement is, the stronger the overlapping magnetic fields from the adjacent coil become, and thus, in many cases, the magnetic field is stronger outside a coil than inside the coil.

When a power supply wire is installed between coils that are adjacent to each other, the distance shortens between the power supply wire and the sides of the coils. Accordingly, it is desirable for the wires of a power supply network to pass through the vicinity of the center inside each coil from the point of view of an increase in the density of the coils. FIG. 1 illustrates such a power supply network.

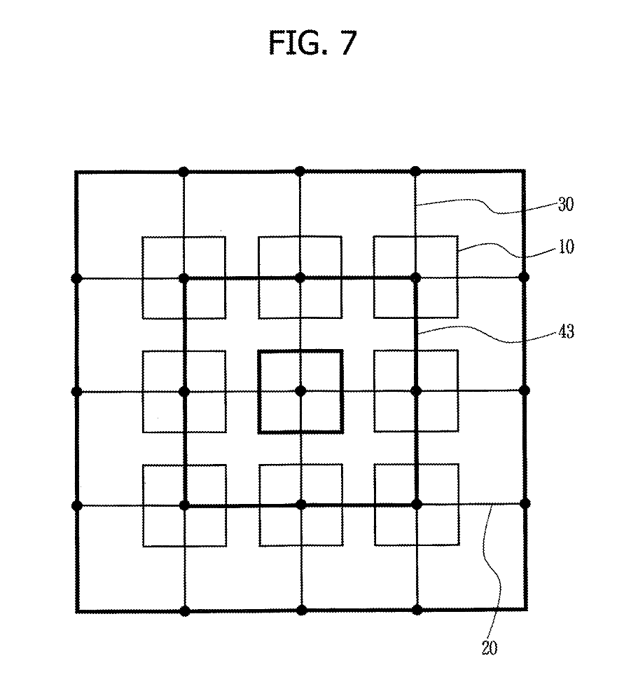

FIG. 7 is a diagram illustrating a closed circuit that is formed in the periphery of a coil and through which an eddy current flows. When the coil at the center is seen, a closed circuit 43 depicted by a thick line that is formed of a first power supply wire group 20 and a second power supply wire group 30 that have connections inside eight coils 10 surrounding the coil at the center provides a path for an eddy current that most greatly affects the inductive coupling in the coil at the center depicted by a thick line. In this case, power supply wire pairs 20 and 30 pass through the center of the coils 10, and therefore, the closed circuit 43 extends around the coil 10 at the center at a distance that is the sum of a length that is 0.5 times greater than the sides D of the coils and the distance of the gaps between the coils.

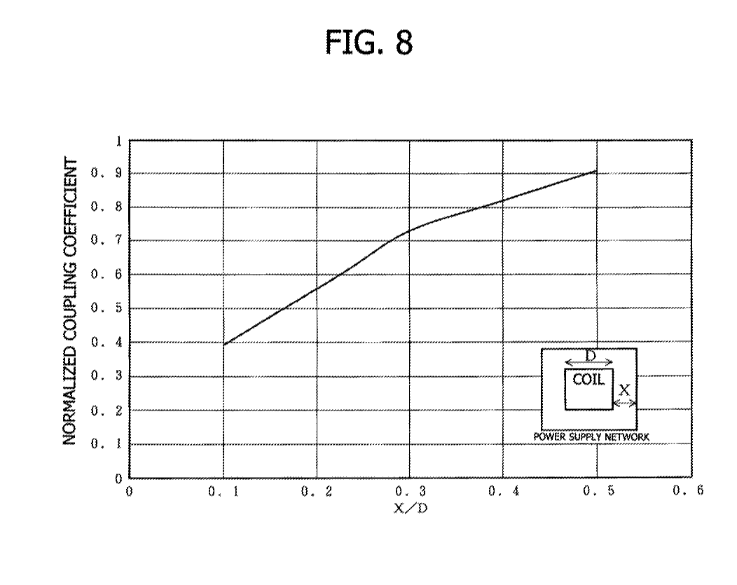

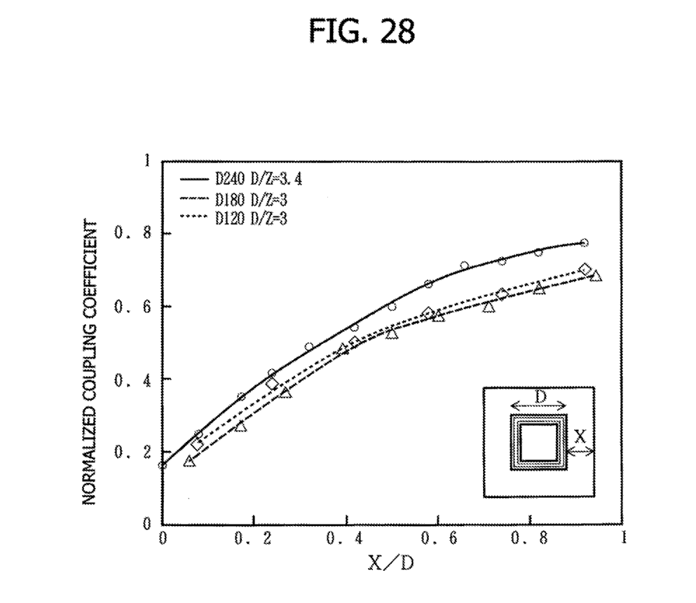

FIG. 8 is a graph illustrating the dependency of the degree of inductive coupling on the distance between the power supply wire network and the sides of the coils, which illustrates values that are gained by normalizing the permeability of the electromagnetic field between the transmission and reception coils that is found using an electromagnetic field simulation with the permeability of the case where the power supply network is not provided. In the case of the arrangement illustrated in FIG. 1, as illustrated in FIG. 7, the closed circuit that most greatly affects the coil that is seen extends around the coil that is seen at a distance that is 0.5 times or more greater of the sides D of the coils away from the sides of the coil that is seen, and therefore, it can be understood that the deterioration in the inductive coupling is 10% or less. In the case of the above-described experiment relating to FIG. 28, wires are hypothetically provided along the sides of the coils.

As described in Patent Literature 1, a second coil array that is arranged at the same intervals as in a first coil array and is formed to have the same multilayered wire structure as the first coil array may be arranged so as to overlap the first coil array with a shift by a predetermined distance. In this case as well, the first power supply wire group is arranged so as to pass through the inside of each coil that forms the second coil array in the X direction as viewed in the direction in which the multilayer wire structure is layered, and the second power supply wire group is arranged so as to pass through the inside of each coil that forms the second coil array in the Y direction as viewed in the direction in which the multilayer wire structure is layered. In this case, the coils that overlap each other carry out electromagnetic field communication in accordance with a time division or a phase division method as described in Patent Literature 1.

In the case where the coils in the first coil array are arranged in proximity to such an extent that it is difficult to arrange power supply wire pairs between the coils, and at the same time, the coils in the second coil array are arranged in proximity to such an extent that it is difficult to arrange power supply wire pairs between the coils, a plurality of power supply wire pairs may be arranged so as to pass through the inside of each coil. In this case, it is desirable for one end of each power supply wire and one end of each ground wire to be an open end.

Here, the multilayered wire structure in which the first coil elements and the second coil elements are formed and the multilayered wire structure in which the first power supply wire group and the second power supply wire group are formed may be provided on the same substrate or different substrates.

The embodiment of the present invention adopts the following configurations.

1) Power supply wire pairs pass through the vicinity of the center of each coil.
2) Power supply wire pairs that intersect in the vicinity of the center of each coil are connected through a via.
3) Power supply wire pairs that pass between the sides of coils where parts of the coils overlap are not connected through a via within the coil column and are connected through a via outside the coil column.

As a result, the following working effects can be gained.

1) The closed circuit that becomes the path of an eddy current can be at a distance that is 0.5 times greater or more than the length of the sides of the coil away from the coil, and therefore, the inductive coupling of the coil can be prevented from being lowered by the power supply wire network.
2) The power supply wire pairs can be arranged densely, and therefore, the electrical resistance of the power supply wire network can be prevented from increasing.
3) The power supply wire pairs pass through the vicinity of the center of each coil, and therefore, the density of the coils for inductive coupling communication can be increased in the layout.

### Example 1

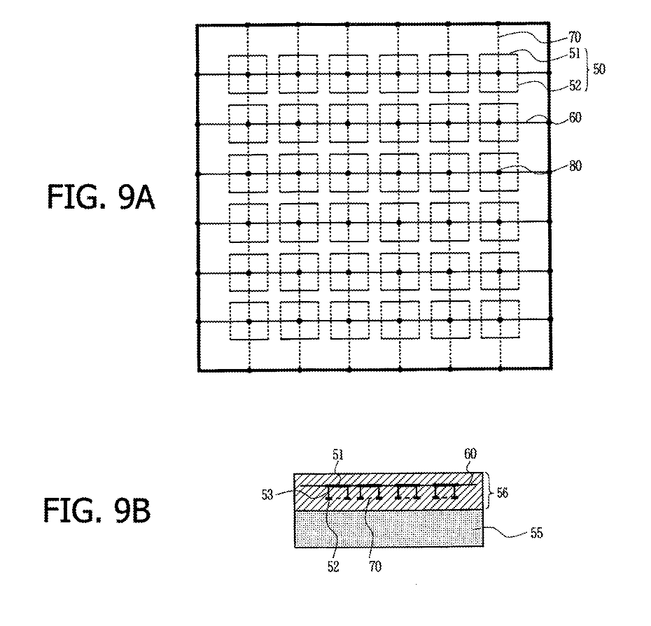

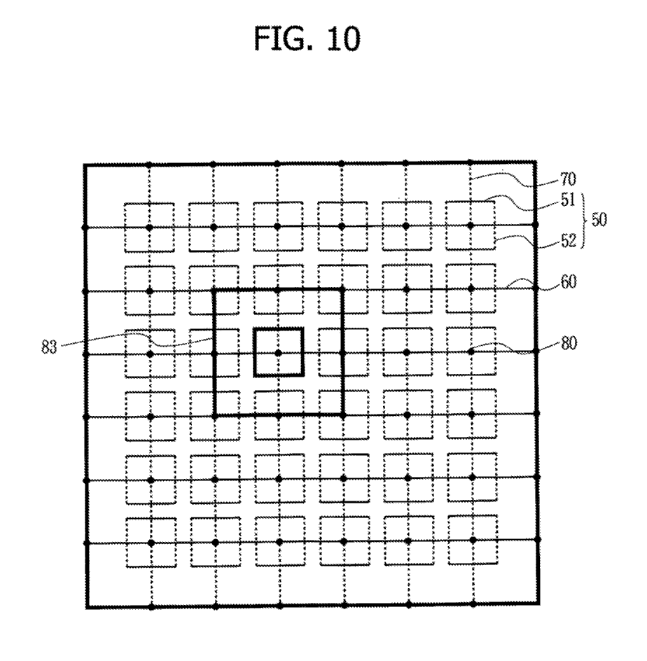

Next, the semiconductor integrated circuit device according to Example 1 of the present invention is described in reference to FIGS. 9A through 10. FIGS. 9A and 9B are diagrams illustrating the semiconductor integrated circuit device according to Example 1 of the present invention. FIG. 9A is a diagram symbolically illustrating an area where a transmission and reception coil array is arranged, and FIG. 9B is a cross-sectional diagram schematically illustrating the area where a transmission and reception coil array is arranged. As illustrated in FIG. 9A, a power supply wire pair 60 passes through the vicinity of the center of each coil 50 in the X direction, and a power supply wire pair 70 passes through the vicinity of the center of each coil 50 in the Y direction. Power supply wires in the power supply wire pair 60 and in the power supply wire pair 70 are connected to each other through a via 80 in the center portion of each coil 50. In addition, ground wires in the power supply wire pair 60 and in the power supply wire pair 70 are connected to each other through a via 80 in the center portion of each coil 50. Though FIG. 9A illustrates a coil array of six rows by six columns, the coil array may be expanded to m rows by n columns.

As illustrated in FIGS. 9A and 9B, each coil 50 is formed by allowing vias 53 to alternately connect coil elements 51 and coil elements 52 made of wires in different layer levels by using a multilayered wire structure 56 formed on a silicon substrate 55. In addition, the power supply wire pairs 60 are formed of wires that are in the same layer as and parallel to the coil elements 51, and the power supply wire pairs 70 are formed of wires that are in the same layer as and parallel to the coil elements 52. Here, the wires in different layer levels are depicted by solid and broken lines, and hereinafter, the difference in the type of lines represents the difference in the layer.

FIG. 10 is a diagram illustrating a closed circuit through which an eddy current flows, where a closed circuit 83 depicted by a thick line most greatly affects the coil to be seen depicted by a thick line. As the result of electrical field simulation, the permeability of the electromagnetic field in Example 1 is 0.90 in the case where the permeability of the case where no power supply network is provided is 1, and thus, the permeability is lowered by 10% and prevented from deteriorating. In the electromagnetic simulation, the length D of the sides of the coils is 100 μm, the gap between the sides of the coils that are adjacent to each other is 20 μm, the wire width of the coil elements is 7 μm, and the wire width of the power supply wires and the ground wires is 10 μm.

As described above, in Example 1, the power supply wire pairs 60 and the power supply wire pairs 70 are arranged so as to pass through the vicinity of the center of each coil 50. The power supply wires of the power supply wire pairs 60 and the power supply wire pairs 70 are connected to each other in the vicinity of the center of each coil 50, and the ground wires of the power supply wire pairs 60 and the power supply wire pairs 70 are connected to each other in the vicinity of the center of each coil 50. Therefore, the density of the coils can be increased in the layout, and at the same time, the power supply voltage in the power supply network can be prevented from dropping.

In addition, the closed circuit through which an eddy current flows that most greatly affects the coil to be seen is formed at a distance 0.5 times greater or more of the length D of the sides of the coils away from the coils, and therefore, the lowering of the inductive coupling due to an eddy current can be suppressed to approximately 10%.

### Example 2

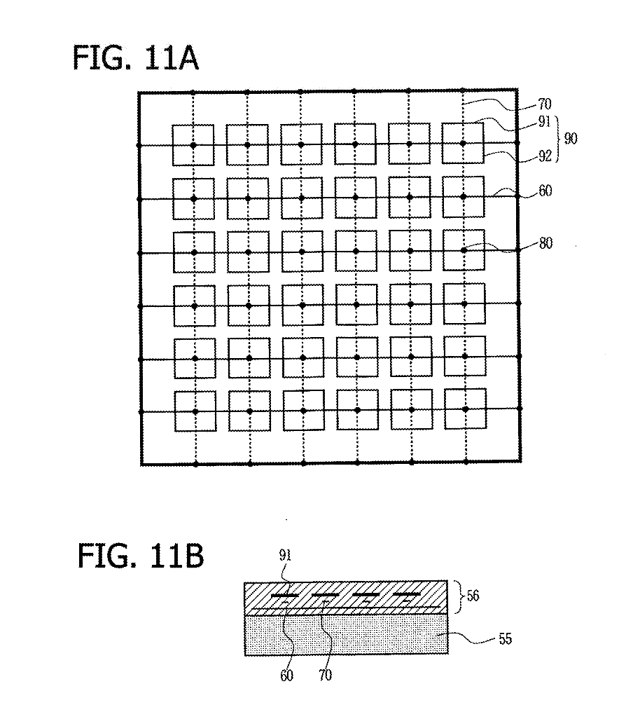

Next, the semiconductor integrated circuit device according to Example 2 of the present invention is described in reference to FIGS. 11A and 11B. FIGS. 11A and 11B are diagrams illustrating the semiconductor integrated circuit device according to Example 2 of the present invention. FIG. 11A is a diagram symbolically illustrating an area where a transmission and reception coil array is arranged, and FIG. 11B is a cross-sectional diagram schematically illustrating the area where a transmission and reception coil array is arranged. As illustrated in FIG. 11A, power supply wire pairs 60 pass through the vicinity of the center of each coil 90 in the X direction as viewed in the direction in which the layers are layered, power supply wire pairs 70 pass through the vicinity of the center of each coil 90 in the Y direction, the power supply wires of the power supply wire pairs 60 and the power supply wire pairs 70 are connected to each other through vias 80, and the ground wires of the power supply wire pairs 60 and the power supply wire pairs 70 are connected to each other through vias 80. Though the coil array illustrated in FIG. 11A has six rows by six columns, the coil array may be expanded to m rows by n columns.

As illustrated in FIGS. 11A and 11B, each coil 90 is a plane spiral coil formed of coil elements 91 and coil elements 92, which are wires in the same layer, in a multilayered wire structure 56 formed on a silicon substrate 55. Accordingly, a power supply wire pair 60 and a power supply wire pair 70 cannot pass through the inside of a coil 90, and therefore, the power supply wire pairs 60 and the power supply wire pairs 70 are formed of wires in a layer level that is different from the layer level of the coil elements 91 and the coil elements 92.

In this case, the closed circuit that most greatly affects the coil to be seen is the same as in Example 1 and can prevent the permeability of the electromagnetic field from deteriorating in the same manner as in Example 1. In addition, the density of the coils in the layout can be increased, and at the same time, the power supply voltage of the power supply network can be prevented from dropping.

### Example 3

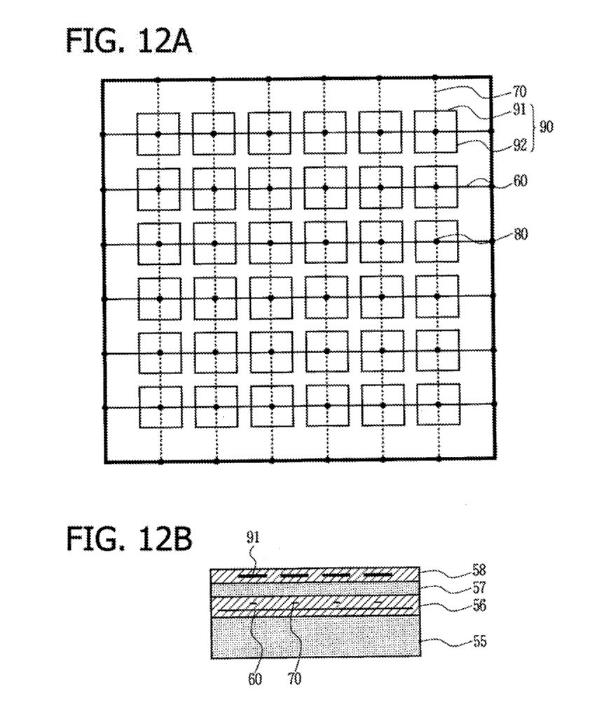

Next, the semiconductor integrated circuit device according to Example 3 of the present invention is described in reference to FIGS. 12A and 12B. FIGS. 12A and 12B are diagrams illustrating the semiconductor integrated circuit device according to Example 3 of the present invention. FIG. 12A is a diagram symbolically illustrating an area where a transmission and reception coil array is arranged, and FIG. 12B is a cross-sectional diagram schematically illustrating the area where a transmission and reception coil array is arranged. As illustrated in FIG. 12A, power supply wire pairs 60 pass through the vicinity of the center of each coil 90 in the X direction as viewed in the direction in which the layers are layered, power supply wire pairs 70 pass through the vicinity of the center of each coil 90 in the Y direction, the power supply wires of the power supply wire pairs 60 and the power supply wire pairs 70 are connected to each other through vias 80, and the ground wires of the power supply wire pairs 60 and the power supply wire pairs 70 are connected to each other through vias 80. Though the coil array illustrated in FIG. 11A has six rows by six columns, the coil array may be expanded to m rows by n columns.

As illustrated in FIGS. 12A and 12B, each coil 90 is a plane spiral coil formed of coil elements 91 and coil elements 92, which are wires in the same layer, in a multilayered wire structure 58 formed on a silicon substrate 57. Accordingly, a power supply wire pair 60 and a power supply wire pair 70 cannot pass through the inside of a coil 90, and therefore, the power supply wire pairs 60 and the power supply wire pairs 70 are formed by using a multilayered wire structure 56 provided on a silicon substrate 55 that is different from the silicon substrate 57 on which a multilayered wire structure that is used to form the coil elements 91 and the coil elements 92 is provided.

In this case, the closed circuit that most greatly affects the coil to be seen is the same as in Example 1 and can prevent the permeability of the electromagnetic field from deteriorating in the same manner as in Example 1. In addition, the density of the coils in the layout can be increased, and at the same time, the power supply voltage of the power supply network can be prevented from dropping.

### Example 4

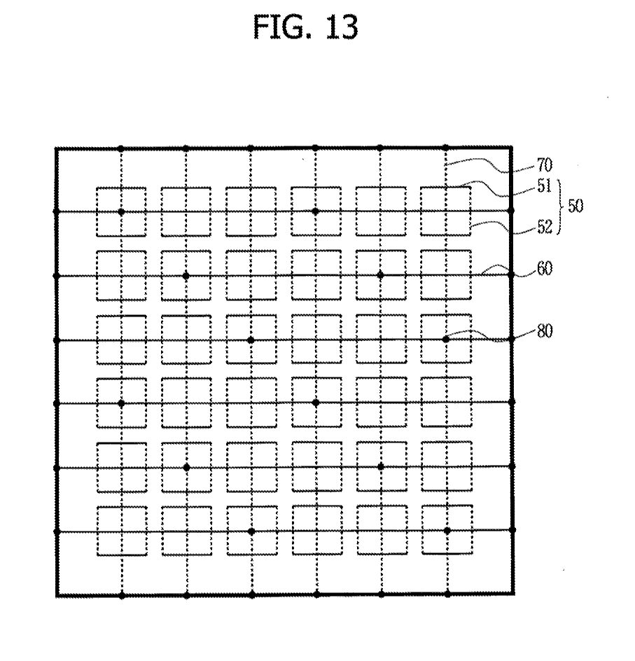

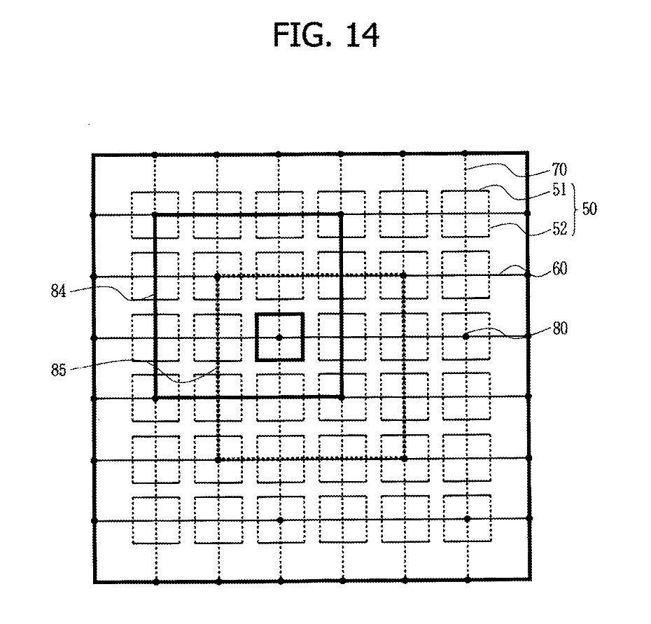

Next, the semiconductor integrated circuit device according to Example 4 of the present invention is described in reference to FIGS. 13 and 14. FIG. 13 is a diagram symbolically illustrating an area where a transmission and reception coil array is arranged in the semiconductor integrated circuit device according to Example 4 of the present invention. As illustrated in FIG. 13, power supply wires of the power supply wire pairs 60 and power supply wire pairs 70 are connected to each other through vias 80, and ground wires of the power supply wire pairs 60 and the power supply wire pairs 70 are connected to each other through vias 80 in the center portion of each coil 50 that is located at predetermined periods. Though the coil array illustrated in FIG. 13 has six rows by six columns, the coil array may be expanded to m rows by n columns.

FIG. 14 is a diagram illustrating closed circuits through which an eddy current flows, that is to say, illustrating a closed circuit 84 depicted by a thick solid line and a closed circuit 85 depicted by a thick broken line which most greatly affect a coil to be seen that is depicted by a thick solid line. According to the result of an electrical field simulation, the permeability of the electromagnetic field in Example 4 is 0.95 in the case where the permeability of the case where no power supply network is provided is 1, and thus, the permeability is lowered by 5% and is prevented from deteriorating. In this electrical field simulation, the length D of the sides of the coils is 100 μm, the distance between the sides of coils that are adjacent to each other is 20 μm, the wire width of the coil elements is 7 μm, and the wire width of the power supply wires and the ground wires is 10 μm.

As described above in Example 4, the power supply wire pairs 60 and the power supply wire pairs 70 are arranged so as to pass through the vicinity of the center of each coil 50, the power supply wires of the power supply wire pairs 60 and the power supply wire pairs 70 are connected to each other in the vicinity of the center of each coil 50 that is arranged at predetermined periods, and the ground wires of the power supply wire pairs 60 and the power supply wire pairs 70 are connected to each other in the vicinity of the center of each coil 50 that is arranged at predetermined periods, and therefore, the permeability of the electromagnetic field can be further prevented from lowering due to an eddy current. Here, the density of the coils can be increased in the layout, and at the same time, the power supply voltage of the power supply network can be prevented from dropping in the same manner as in Example 1.

In Example 4, coil elements 51 and coil elements 52 are formed of wires in different layer levels in the same manner as in Example 1; however, plane spiral coils may be provided in the same manner as in Example 2 or Example 3. In this case, the power supply wire pairs 60 and the power supply wire pairs 70 may be formed by using a multilayered wire structure provided on the same chip as the coil elements 51 and the coil elements 52 in the same manner as in Example 2. Alternatively, the power supply wire pairs 60 and the power supply wire pairs 70 may be formed by using a multilayered wire structure provided in a chip that is different from the chip in which the multilayered wire structure that is used to form the coil elements 51 and the coil elements 52 is provided in the same manner as in Example 3.

### Example 5

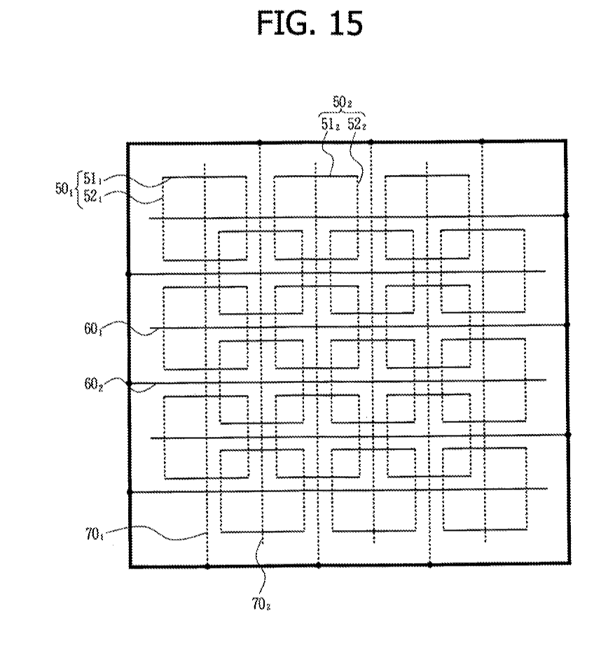

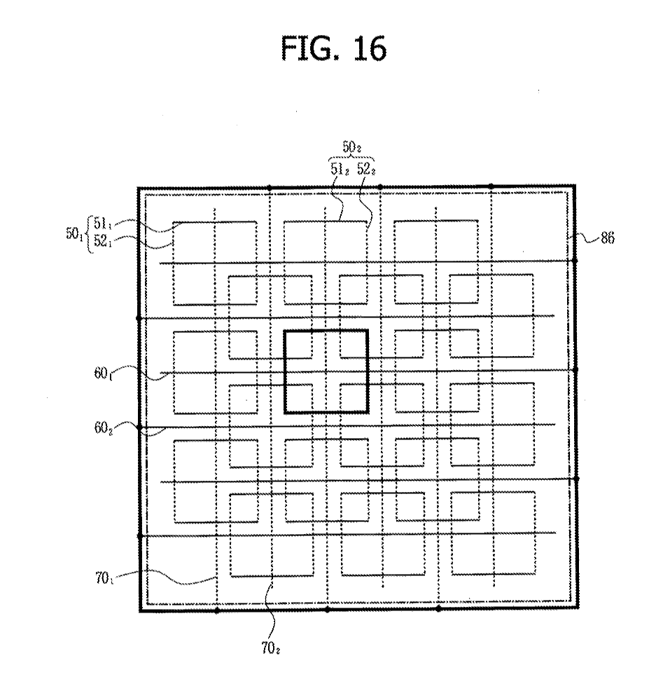

Next, the semiconductor integrated circuit device according to Example 5 of the present invention is described in reference to FIGS. 15 and 16. FIG. 15 is a diagram symbolically illustrating an area where a transmission and reception coil array is arranged in the semiconductor integrated circuit device according to Example 5 of the present invention. As illustrated in FIG. 15, a first coil array formed of coils 50₁ and a second coil array made of coils 50₂ that has the same structure as the first coil array are arranged in such a manner that a coil 50₁ and a coil 50₂ overlap with a shift. This arrangement becomes possible by making the layer level in which coil elements 51₁ and 51₂ are formed of wires different from the layer level in which coil elements 52₁ and 52₂ are formed of wires.

In addition, one end of the power supply wire pairs 60₁ and 60₂ and one end of the power supply wire pairs 70₁ and 70₂ are open ends so that a power supply wire pair 60₁ or 60₂ and a power supply wire pair 70₁ or 70₂ are not connected inside a coil 50₁ or 50₂. In this case, the coils that overlap each other carry out electromagnetic field communication in accordance with a time division or phase division method. Though the respective coil arrays illustrated in FIG. 15 have three rows by three columns, the coil arrays may be expanded to m rows by n columns.

FIG. 16 is a diagram illustrating a closed circuit through which an eddy current flows, where a power supply wire pair 60₁ or 60₂ and a power supply wire pair 70₁ or 70₂ are not connected inside each coil 50₁ or 50₂, and therefore, a closed circuit 86 that most greatly affects the coil to be seen depicted by a thick line is formed outside the coil arrays. Accordingly, the closed circuit 86 is at a great distance away from the sides of each coil 50₁ or 50₂, which can greatly reduce the effects due to an eddy current. Here, in order to make it easier to understand, the closed circuit 86 is depicted by a single-dotted chain line inside the actual closed circuit. Alternatively, the power supply wire pair 60₁ or 60₂ and the power supply wire pair 70₁ or 70₂ may be connected in the periphery of the coil columns so that power supply wire pairs connecting the connection portions form a closed circuit.

### Example 6

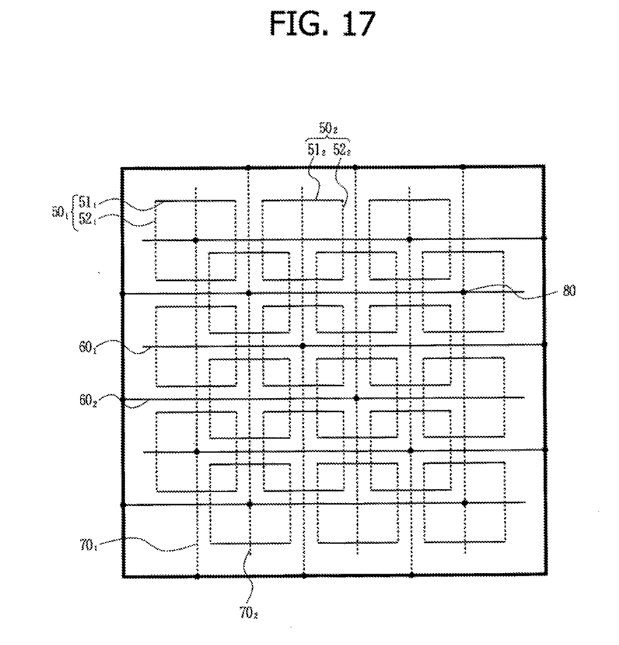

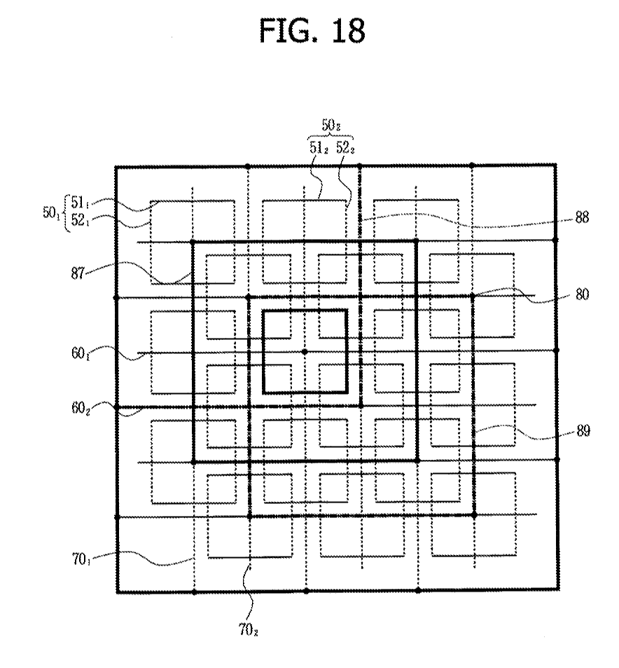

Next, the semiconductor integrated circuit device according to Example 6 of the present invention is described in reference to FIGS. 17 and 18. FIG. 17 is a diagram symbolically illustrating an area where a transmission and reception coil array is arranged in the semiconductor integrated circuit device according to Example 6 of the present invention, where the arrangements of the coils and the power supply wire pairs are the same as in Example 5. However, a power supply wire pair 60₁ or 60₂ and a power supply wire pair 70₁ or 70₂ are connected in the center portion of a coil 50₁ or 50₂ that is arranged at predetermined periods in Example 6. In this case as well, the coils that overlap each other carry out electromagnetic field communication in accordance with a time division or phase division method. Though the respective coil arrays illustrated in FIG. 17 have three rows by three columns, the coil arrays may be expanded to m rows and n columns.

FIG. 18 is a diagram illustrating closed circuits through which an eddy current flows, where three closed circuits that most greatly affect the coil 50₁ to be seen, which is at the center and is depicted by a thick line, that is to say, a closed circuit 87 depicted by a thick solid line, a closed circuit 88 depicted by a thick, single-dotted chain line, and a closed circuit 89 depicted by a thick, double-dotted chain line are formed. Though two sides out of the sides of the closed circuit 88 or 89 are partially located in proximity to a side of the coil 50₁ to be seen at the center with a distance of 0.5 D or less, the other portions are at a considerably longer distance away, which makes the effects from an eddy current smaller.

### Example 7

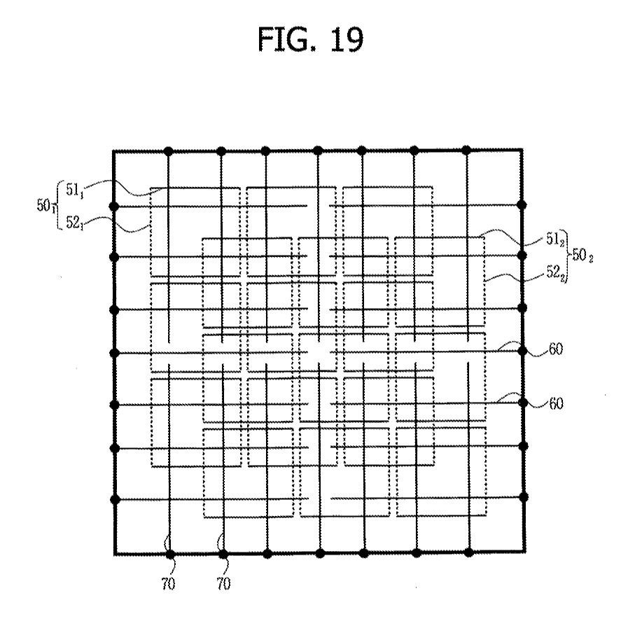

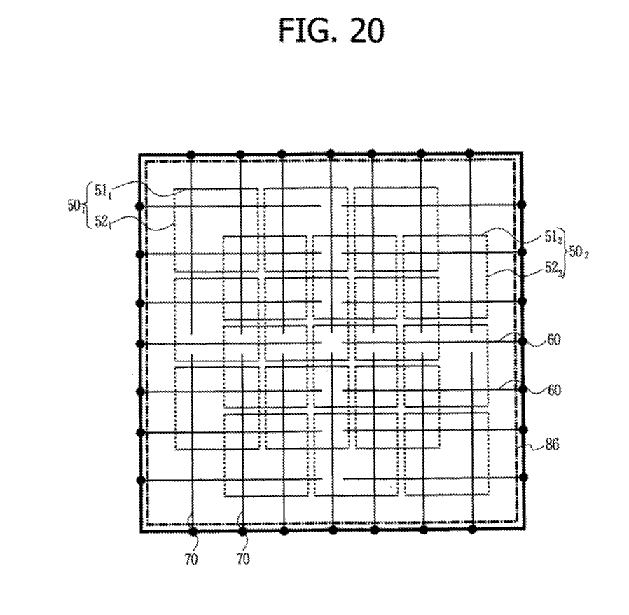

Next, the semiconductor integrated circuit device according to Example 7 of the present invention is described in reference to FIGS. 19 and 20. FIG. 19 is a diagram symbolically illustrating an area where a transmission and reception coil array is arranged in the semiconductor integrated circuit device according to Example 7 of the present invention. As illustrated in FIG. 19, a first coil array formed of coils 50₁ and a second coil array made of coils 50₂ that has the same structure as the first coil array are arranged in such a manner that a coil 50₁ and a coil 50₂ overlap with a shift. This arrangement becomes possible by making the layer level in which coil elements 51₁ and 51₂ are formed of wires different from the layer level in which coil elements 52₁ and 52₂ are formed of wires.

Here, the coils 50₁ and 50₂ are arranged in such a density that a power supply wire pair 60 or a power supply wire pair 70 cannot be arranged between coils 50₁ and 50₂ that are adjacent to each other in each coil array. Therefore, the power supply wire pairs 60 and 70 are arranged so that two power supply wire pairs 60 and two power supply wire pairs 70 pass through the inside of each coil 50₁ or 50₂. In addition, the respective power supply wire pairs 60 and 70 are made of fishbone-shaped wires where they are disconnected in the vicinity of the center portions. In this case as well, coils that overlap on top of each other carry out time division or phase division electromagnetic field communication. Though FIG. 19 illustrates each coil array as having three rows and three columns, the coil array may be expanded to m rows by n columns.

FIG. 20 is a diagram illustrating a closed circuit through which an eddy current flows, where the power supply wire pair 60 and the power supply wire pair 70 are not connected inside each coil 50₁ or 50₂, and therefore, a closed circuit 86 that most greatly affects the coil to be seen is formed outside the coil arrays. Accordingly, the closed circuit 86 is at a great distance away from the sides of each coil 50₁ or 50₂, which can greatly reduce the effects due to an eddy current. Here, in order to make it easier to understand, the closed circuit 86 is depicted by a single-dotted chain line inside the actual closed circuit. Alternatively, the power supply wire pair 60 and the power supply wire pair 70 may be connected in the periphery of the coil columns so that power supply wire pairs connecting the connection portions form a closed circuit.

### Example 8

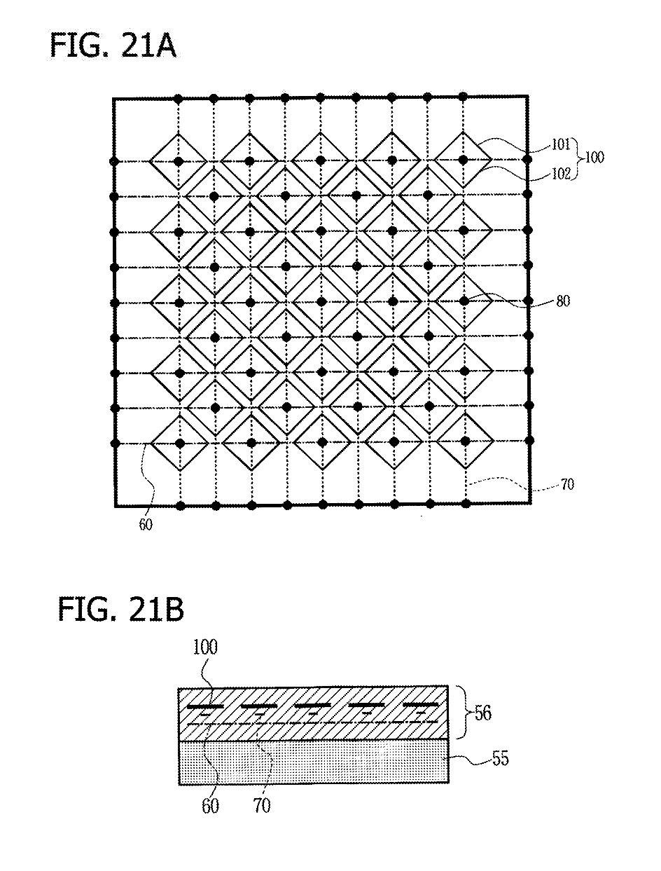

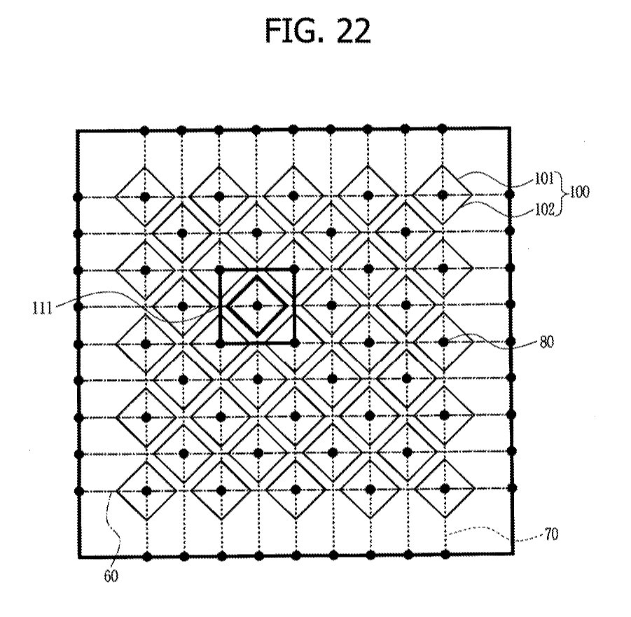

Next, the semiconductor integrated circuit device according to Example 8 of the present invention is described in reference to FIGS. 21A through 22. FIGS. 21A and 21B are diagrams illustrating the semiconductor integrated circuit device according to Example 8 of the present invention. FIG. 21A is a diagram symbolically illustrating an area where a transmission and reception coil array is arranged, and FIG. 21B is a cross-sectional diagram schematically illustrating the area where a transmission and reception coil array is arranged. As illustrated in FIG. 21A, power supply wire pairs 60 pass through the vicinity of the center of each coil 100 in the X direction, power supply wire pairs 70 pass through the vicinity of the center of each coil 100 in the Y direction, the power supply wires of the power supply wire pairs 60 and the power supply wire pairs 70 are connected to each other through vias 80, and the ground wires of the power supply wire pairs 60 and the power supply wire pairs 70 are connected to each other through vias 80 in the vicinity of the center of each coil 100. In Example 8, however, each coil 100 is diamond-shaped made of coil elements 101 formed of wires that are inclined by 45° relative to the power supply wire pairs 60 and coil elements 102 formed of wires that are inclined by 45° relative to the power supply wire pairs 70. Though the coil array illustrated in FIG. 21A has an arrangement of six rows by five columns within the outermost periphery, the coil array may be expanded to m rows by n columns.

As illustrated in FIG. 21B, each coil 100 is a plane spiral coil formed of coil elements 101 and coil elements 102, which are wires in the same layer, in a multilayered wire structure 56 formed on a silicon substrate 55. Accordingly, a power supply wire pair 60 and a power supply wire pair 70 cannot pass through the inside of a coil 100, and therefore, the power supply wire pairs 60 and the power supply wire pairs 70 are formed of wires in a layer level that is different from the layer level in which the coil elements 101 and the coil elements 102 are formed.

FIG. 22 is a diagram illustrating a closed circuit through which an eddy current flows, where a closed circuit 111 which most greatly affects a coil to be seen that is depicted by a thick line is depicted by a thick solid line. According to the result of an electrical field simulation, the permeability of the electromagnetic field in Example 8 is 0.80 in the case where the permeability of the case where no power supply network is provided is 1, and thus, the permeability is lowered by 20% and is prevented from deteriorating. In this electrical field simulation, the length D of the sides of the coils is 100 μm, the distance between the sides of coils that are adjacent to each other is 20 μm, the wire width of the coil elements is 7 μm, and the wire width of the power supply wires and the ground wires is 10 μm.

As described above, the coil elements are inclined by 45° relative to the power supply wire pairs in Example 8, and therefore, cross-talk between the coils and the power supply wire pairs that are arranged in the X and Y directions can be reduced as described in Patent Literature 2. As can be understood from the Biot-Savart law (the formula for calculating a microscopic magnetic field that is generated by a current element having a microscopic length in a location r away from the current element), the eddy currents can be effectively reduced when the power supply network and the coil sides face diagonally, which makes the distance greater and provides an angle between the two. In the case of Example 8 as well, coils 100 may be formed by connecting coil elements in different layer levels in the same manner as in Example 1. Alternatively, coils 100 may be formed by using multilayered wire structures where coil elements or power supply wire pairs are formed and which are provided in different chips as in Example 3.

### Example 9

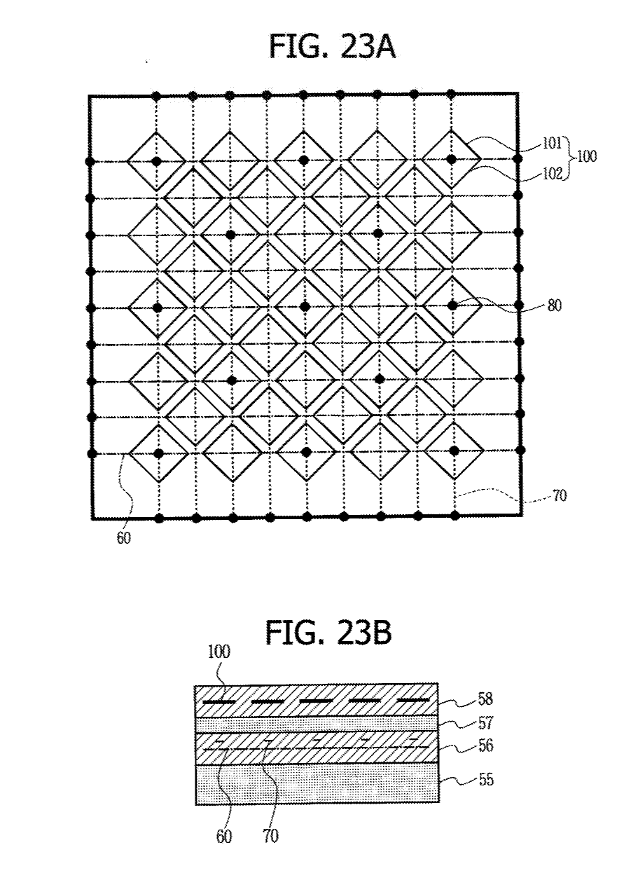

Next, the semiconductor integrated circuit device according to Example 9 of the present invention is described in reference to FIGS. 23A through 25. FIGS. 23A and 23B are diagrams illustrating the semiconductor integrated circuit device according to Example 9 of the present invention. FIG. 23A is a diagram symbolically illustrating an area where a transmission and reception coil array is arranged, and FIG. 23B is a cross-sectional diagram schematically illustrating the area where a transmission and reception coil array is arranged. As illustrated in FIG. 23A, power supply wire pairs 60 pass through the vicinity of the center of each coil 100 in the X direction, power supply wire pairs 70 pass through the vicinity of the center of each coil 100 in the Y direction in the same manner as in Example 8. In Example 9, however, the power supply wires of the power supply wire pairs 60 and the power supply wire pairs 70 are connected to each other through vias 80, and the ground wires of the power supply wire pairs 60 and the power supply wire pairs 70 are connected to each other through vias 80 in the vicinity of the center of the coils 100 that are arranged at predetermined periods. Though the coil array illustrated in FIG. 23A has an arrangement of six rows by five columns within the outermost periphery, the coil array may be expanded to m rows by n columns.

As illustrated in FIG. 23B, each coil 100 is a plane spiral coil formed of coil elements 101 and coil elements 102, which are wires in the same layer, in a multilayered wire structure 58 formed on a silicon substrate 57. Accordingly, a power supply wire pair 60 and a power supply wire pair 70 cannot pass through the inside of a coil 100, and therefore, the power supply wire pairs 60 and the power supply wire pairs 70 are formed by using a multilayered wire structure 56 formed on a silicon substrate 55, which is different from the silicon substrate on which the multilayered wire structure for the coil elements 101 and the coil elements 102 is formed.

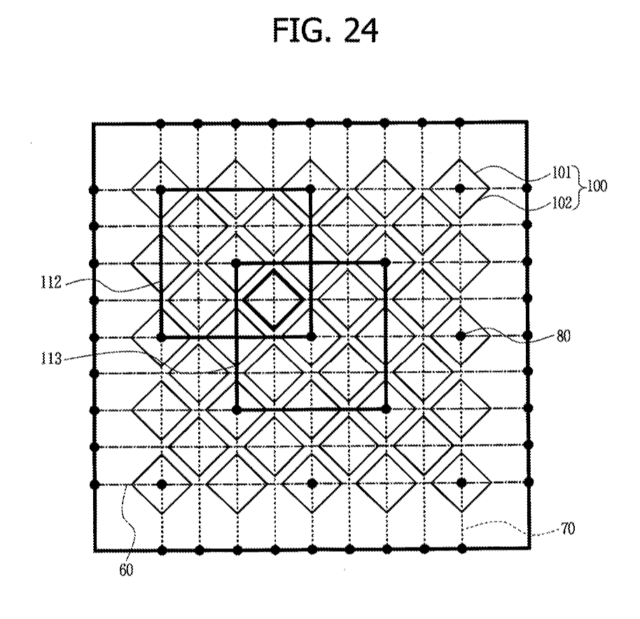

FIG. 24 is a diagram illustrating closed circuits through which an eddy current flows. Here, a coil, inside of which a power supply wire pair 60 and a power supply wire pair 70 are not connected in the location they intersect at, is to be seen, and two closed circuits 112 and 113 denoted by thick solid lines most greatly affect the coil to be seen that is denoted by a thick line. According to the results of an electrical field simulation, the permeability of the electromagnetic field in Example 9 is 0.88 in the case where the permeability of the case where no power supply network is provided is 1, and thus, the permeability is lowered by 12% and prevented from deteriorating. In the electrical field simulation, the length D of the sides of the coil is 100 μm, the distance between the sides of the coils that are adjacent to each other is 20 μm, the wire width of the coil elements is 7 μm, and the wire width of the power supply wires and the ground wires is 10 μm.

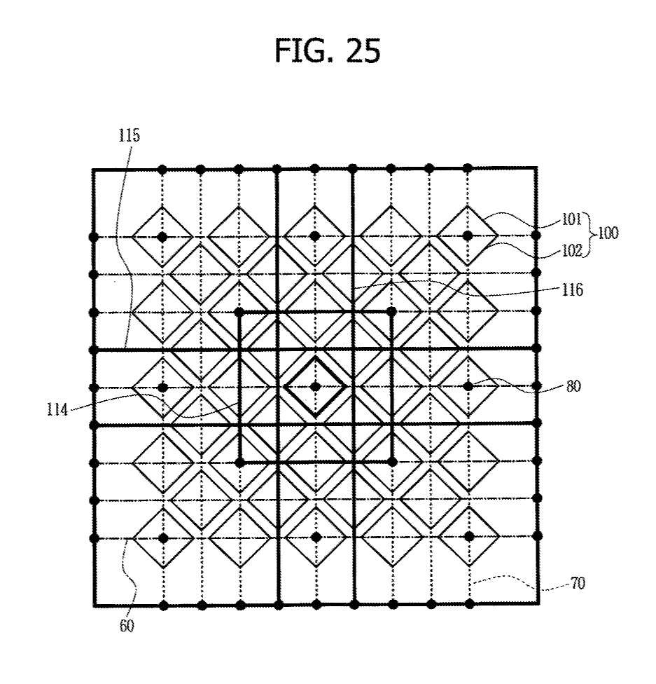

FIG. 25 is a diagram illustrating closed circuits through which an eddy current flows. Here, a coil, inside of which a power supply wire pair 60 and a power supply wire pair 70 are connected in the locations they intersect at, is to be seen, three closed circuits that are denoted by thick solid lines, a square closed circuit 114 and two large, rectangular closed circuits 115 and 116, most greatly affect the coil to be seen that is denoted by a thick line. According to the results of an electrical field simulation, the permeability of the electromagnetic field in this case is 0.90 in the case where the permeability of the case where no power supply network is provided is 1, and thus, the permeability is lowered by 10% and prevented from deteriorating.

As described above, the power supply wires in the power supply wire pairs 60 and the power supply wire pairs 70 are connected to each other, and the ground wires in the power supply wire pairs 60 and the power supply wire pairs 70 are connected to each other in the center portion of the coils 100 that are arranged at predetermined periods in Example 9, which makes the average distance between a side of the coils and a power supply wire pair greater than that in Example 8, and thus, the effects of eddy currents can be weakened. In the case of Example 9 as well, coils 100 may be formed by connecting coil elements in different layer levels to each other in the same manner as in Example 1. Alternatively, coils 100 may be formed by using a multilayered wire structure where the coil elements and the power supply wire pairs are formed in the same chip in the same manner as in Example 8.

### Example 10

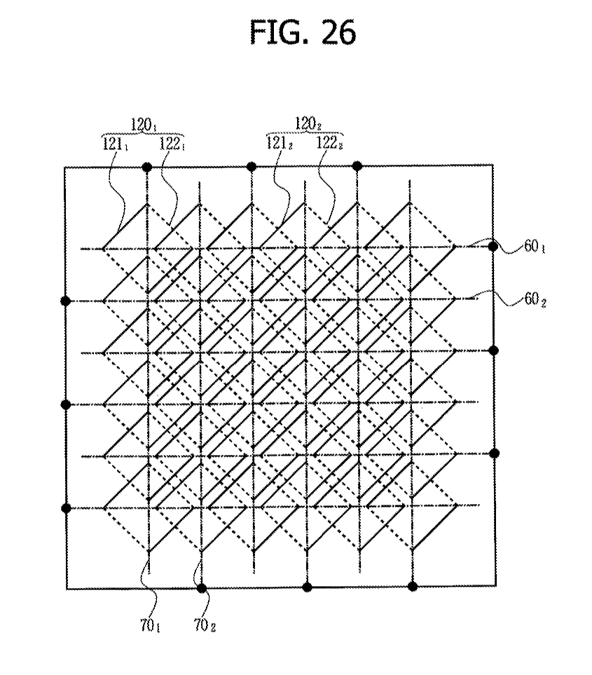

Next, the semiconductor integrated circuit device according to Example 10 of the present invention is described in reference to FIG. 26. FIG. 26 is a diagram symbolically illustrating an area where transmission and reception coil arrays are arranged in the semiconductor integrated circuit device according to Example 10 of the present invention. As illustrated in FIG. 26, a first coil array formed of coils 120₁ and a second coil array formed of coils 120₂ having the same structure as the first coil array are arranged in such a manner that the coils 120₁ and the coils 120₂ overlap with a shift. This arrangement becomes possible by making the layer level in which coil elements 121₁ and 121₂ are formed of wires different from the layer level in which coil elements 122₁ and 122₂ are formed of wires.

In addition, one end of the power supply wire pairs 60₁ and 60₂ and one end of the power supply wire pairs 70₁ and 70₂ are open ends so that the power supply wire pair 60₁ and the power supply wire pair 70₁ are not connected inside the coil 120₁, and the power supply wire pair 60₂ and the power supply wire pair 70₂ are not connected inside the coil 120₂. In this case, the coils that overlap each other carry out time division or phase division electromagnetic field communication. Though FIG. 26 illustrates each coil array as having three rows by three columns, the coil array may be expanded to m rows by n columns.

In this case, the closed circuits through which an eddy current flows are the same as described above in Example 5. That is to say, a closed circuit that most greatly affects a coil to be seen is formed outside the coil array. Accordingly, the closed circuit is a great distance away from the sides of each coil 120₁ or 120₂, and therefore, the effects due to an eddy current can be greatly reduced. Alternatively, the power supply wire pair 60₁ and the power supply wire pair 70₁ may be connected, or the power supply wire pair 60₂ and the power supply wire pair 70₂ may be connected in the periphery of the coil columns in such a manner that the power supply wire pairs connecting the connected portions form a closed circuit.

In this case, in the same manner as in Example 7, the coils 120₁ may be arranged close to each other to such an extent that the power supply wire pairs 60₁ and the power supply wire pairs 70₁ cannot be arranged between the coils 120₁ that are adjacent to each other in the coil array, and the coils 120₂ may be arranged close to each other to such an extent that the power supply wire pairs 60₂ and the power supply wire pairs 70₂ cannot be arranged between the coils 120₂ that are adjacent to each other in the coil array. In this case, the power supply wire pairs 60 and 70 are arranged so that two power supply wire pairs 60 and two power supply wire pairs 70 pass through the inside of each coil 120₁ or 120₂. In addition, the respective power supply wire pairs 60 and 70 are formed of fishbone-shaped wires that are disconnected in the vicinity of the center portions.

### Example 11

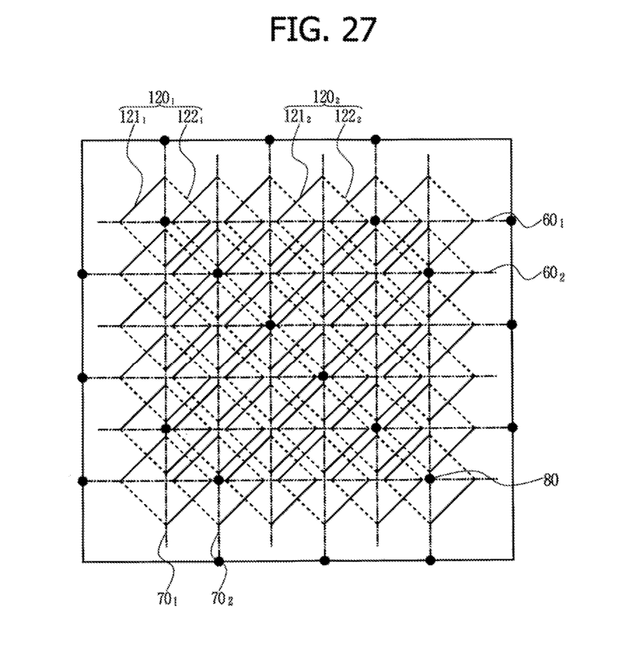

Next, the semiconductor integrated circuit device according to Example 11 of the present invention is described in reference to FIG. 27. FIG. 27 is a diagram symbolically illustrating an area where transmission and reception coil arrays are arranged in the semiconductor integrated circuit device according to Example 10 of the present invention. As illustrated in FIG. 26, a first coil array formed of coils 120₁ and a second coil array formed of coils 120₂ having the same structure as the first coil array are arranged in such a manner that the coils 120₁ and the coils 120₂ overlap with a shift. This arrangement becomes possible by making the layer level in which coil elements 121₁ and coil elements 122₁ are formed of wires different from the layer level in which coil elements 121₂ and coil elements 122₂ are formed of wires.

In addition, one end of the power supply wire pairs 60₁ and 60₂ and one end of the power supply wire pairs 70₁ and 70₂ are open ends so that the power supply wire pair 60₁ and the power supply wire pair 70₁ are connected inside the coil 120₁, and the power supply wire pair 60₂ and the power supply wire pair 70₂ are connected inside the coil 120₂ where the coils are located at predetermined periods. In this case, the coils that overlap each other carry out time division or phase division electromagnetic field communication. Though FIG. 27 illustrates each coil array as having three rows by three columns, the coil array may be expanded to m rows by n columns.

In this case, a plurality of closed circuits through which an eddy current flows and that most greatly affect a coil to be seen is formed in the same manner as described above in Example 6; however, they all have a great distance vis-a-vis the sides of the coils, and therefore, the effects due to eddy currents can be reduced greatly.

### REFERENCE SIGNS LIST

10, 10₁, 10₂ coil
11 first coil element
12 second coil element
13 via
20 first power supply wire group
21, 31 power supply wire
22, 32 ground wire
30 second power supply wire group
41, 42 via
43 closed circuit
50, 50₁, 50₂, 90, 100, 100₁, 100₂, 120₁, 120₂ coil
51, 52, 91, 92, 101, 101₁, 101₂, 102, 102₁, 102₂, 121₁, 121₂, 122₁, 122₂ coil elements
53, 80 via
55, 57 silicon substrate
56, 58 multilayered wire structure
60, 60₁, 60₂, 70, 70₁, 70₂ power supply wire pairs
83, 84, 85, 86, 87, 88, 89, 111, 112, 113, 114, 115, 116 closed circuit

1. A semiconductor integrated circuit device, comprising:
a first coil array made of a plurality of coils for transmitting and receiving a signal, that are formed in the same level in a multilayered wire structure provided on a substrate and are arranged at predetermined intervals; and
a power supply network having a first power supply wire group made of power supply wire pairs of a power supply wire and a ground wire that pass through the inside of every coil in the X direction as viewed in the direction in which the multilayered wire structure is layered, and a second power supply wire group made of power supply wire pairs of a power supply wire and a ground wire that pass through the inside of every coil in the Y direction that is orthogonal to the X direction as viewed in the direction in which the multilayered wire structure is layered, wherein
at least part of the first power supply wire group and at least part of the second power supply wire group form a closed circuit that surrounds the periphery of each coil.

2. The semiconductor integrated circuit device according to claim 1, wherein the coils are formed of first coil elements that are parallel to the first power supply wire group and second coil elements that are parallel to the second power supply wire group.

3. The semiconductor integrated circuit device according to claim 2, wherein
the first coil elements and the second coil elements are formed of wires in different layer levels, and
the first coil elements and the second coil elements are connected alternately through vias.

4. The semiconductor integrated circuit device according to claim 3, wherein
a second coil array where a plurality of coils is arranged with the same intervals as in the first coil array is formed in the multilayered wire structure and arranged so as to overlap the first coil array with a predetermined shift,
the first power supply wire group passes through the inside of all the coils that form the second coil array in the X direction as viewed in the direction in which the multilayered wire structure is layered, and
the second power supply wire group passes through the inside of all the coils that form the second coil array in the Y direction as viewed in the direction in which the multilayered wire structure is layered.

5. The semiconductor integrated circuit device according to claim 2, wherein
the first coil elements and the second coil elements are formed of wires in the same layer level, and
the first power supply wire group and the second power supply wire group are formed of wires in a layer level that is different from the layer level of the first coil elements and the second coil elements.

6. The semiconductor integrated circuit device according to claim 2, wherein the first coil elements, the second coil elements, the first power supply wire group and the second power supply wire group are formed in the multilayered wire structures provided on the same substrate.

7. The semiconductor integrated circuit device according to claim 2, wherein the multilayered wire structure in which the first coil elements and the second coil elements are formed and the multilayered wire structure in which the first power supply wire group and the second power supply wire group are formed are provided on different substrates.

8. The semiconductor integrated circuit device according to claim 1, wherein the coils are formed of third coil elements in a direction that is diagonal to the first power supply wire group and fourth coil elements in a direction that is diagonal to the second power supply wire group.

9. The semiconductor integrated circuit device according to claim 8, wherein
the third coil elements and the fourth coil elements are formed of wires in different layer levels, and
the third coil elements and the fourth coil elements are connected alternately through vias.

10. The semiconductor integrated circuit device according to claim 9, wherein
a second coil array where a plurality of coils is arranged with the same intervals as in the first coil array is formed in the multilayered wire structure and arranged so as to overlap the first coil array with a predetermined shift,
the first power supply wire group passes through the inside of all the coils that form the second coil array in the X direction as viewed in the direction in which the multilayered wire structure is layered, and
the second power supply wire group passes through the inside of all the coils that form the second coil array in the Y direction as viewed in the direction in which the multilayered wire structure is layered.

11. The semiconductor integrated circuit device according to claim 8, wherein
the third coil elements and the fourth coil elements are formed of wires in the same layer level, and
the first power supply wire group and the second power supply wire group are formed of wires in a layer level that is different from the layer level of the third coil elements and the fourth coil elements.

12. The semiconductor integrated circuit device according to claim 8, wherein the third coil elements, the fourth coil elements, the first power supply wire group and the second power supply wire group are formed in the multilayered wire structure provided on the same substrate.

13. The semiconductor integrated circuit device according to claim 8, wherein the multilayered wire structure in which the third coil elements and the fourth coil elements are formed and the multilayered wire structure in which the first power supply wire group and the second power supply wire group are formed are provided on different substrates.

14. The semiconductor integrated circuit device according to claim 1, wherein the first power supply wire group and the second power supply wire group are connected through the inside of all the coils.

15. The semiconductor integrated circuit device according to claim 1, wherein the first power supply wire group and the second power supply wire group are connected through the inside of some of the coils.

16. The semiconductor integrated circuit device according to claim 15, wherein the first power supply wire group and the second power supply wire group are connected at predetermined periods through the inside of coils.

17. The semiconductor integrated circuit device according to claim 1, wherein one end of the first power supply wire group and one end of the second power supply wire group are open ends.

18. The semiconductor integrated circuit device according to claim 4, wherein
a plurality of the power supply wire pairs passes through the inside of each coil that forms the first coil array and the inside of each coil that forms the second coil array, and
one end of the first power supply wire group and one end of the second power supply wire group are open ends.

19. The semiconductor integrated circuit device according to claim 10, wherein
a plurality of the power supply wire pairs passes through the inside of each coil that forms the first coil array and the inside of each coil that forms the second coil array, and
one end of the first power supply wire group and one end of the second power supply wire group are open ends.
